(19) United States
(12) Patent Application Publication
(10) Pub. No.: US 2002/0168590 A1
(43) Pub. Date: Nov. 14, 2002

(54) Method of forming storage nodes in a DRAM

(76) Inventors: Jiunn-Ren Hwang, Tai-Chung City (TW); Anseime Chen, Hsin-Chu City (TW); I-Hsiung Huang, Kao-Hsiung City (TW)

Correspondence Address: NAIPO (NORTH AMERICA INTERNATIONAL PATENT OFFICE), P.O. BOX 506, MERRIFIELD, VA, 22116, US

(21) Appl. No.: 09/851,580

(22) Filed: May 10, 2001

(51) Int. Cl. G03F 7/00

(52) U.S. Cl. 430/313; 430/311; 430/312; 430/394

(57) ABSTRACT

A dynamic random access memory (DRAM) is formed on a semiconductor wafer, the semiconductor wafer including a substrate, a thin film layer positioned on the substrate, and a photoresist layer positioned on the thin film layer. Two exposure processes are employed. The first exposure process forms first exposure regions that are linear and parallel with each other on the photoresist layer. The second exposure process forms second exposure regions that are interlaced with and perpendicular to each other on the photoresist layer. Performing a development process to the wafer removes the first exposure regions and the second exposure regions of the photoresist layer to form an array photoresist layer on the thin film layer. The array photoresist layer functions as a mask to perform an etching process to the thin film layer for forming an array thin film layer, the array thin film layer acting as a storage nodes in the DRAM.

### BACKGROUND OF THE INVENTION

1. Field of the Invention

The present invention relates to a method offorming storage nodes in a dynamic random access memory (DRAM) on a semiconductor wafer, and more particularly, to a pattern transfer photolithographic process preventing the occurrence of endof-line shortening.

2. Description of the Prior Art

The photolithographic process is the most important step in semiconductor fabrication. It transfers the layout of a designed integrated circuit onto a semiconductor wafer. In order to form a desired integrated circuit, a mask is initially made and a circuit design pattern is then formed on the mask. A photolithographic process is used to transfer the circuit design pattern onto a photoresist layer on a surface of the semiconductor wafer.

As the complexity and the integration of semiconductor circuits increases, the size of the circuit design pattern on the photoresist layer decreases. However, the critical dimensions of the pattern on the photoresist layer are limited by the resolution limit of the optical exposure tool. Optical proximity effects can easily occur in the photolithographic process during the formation of highly integrated circuit design patterns on a semiconductor wafer. Optical proximity effects cause overexposure or underexposure at the corners of the design patterns on the photoresist layer, which results in a loss of resolution that causes end-of-line shortening of the design pattern. In other words, optical proximity effects cause a difference between the pattern transferred onto the photoresist layer and the actual design pattern.

Please refer to FIG. 1 to FIG. 3 of diagrams of a photolithographic process of forming storage nodes in a dynamic random access memory (DRAM) on a semiconductor wafer according the prior art. The photolithographic process is used to define the position and the size of a storage node of a DRAM on a semiconductor wafer 10. As shown in FIG. 1, the semiconductor wafer 10 comprises a silicon substrate 12, a dielectric layer 13 formed of silicon oxide, a plurality of node contacts 14 formed of doped polysilicon in the dielectric layer 13, and an amorphous silicon layer 16 positioned on a surface of the dielectric layer 13 and covering each node contact 14. The amorphous silicon layer 16 is used to form storage nodes of the DRAM, and a photoresist layer 18 covers all a surface of the wafer 10.

The photoresist layer 18 can be either a positive or a negative photoresist. A light beam penetrates through the transparent areas of the mask pattern to the photoresist layer 18 on the substrate 12 and causes the photoresist to undergo a photochemical transformation during the exposure process. If the photoresist layer 18 is formed of positive photoresist, an unexposed positive photoresist will remain after a subsequent development and resin process, and the remaining exposed positive photoresist layer has a same pattern as the mask pattern. If the photoresist layer 18 is formed of negative photoresist, the unexposed negative photoresist is removed in the subsequent development and resin process, and a remaining exposed negative photoresist is complementary to the mask pattern. A photoresist layer mentioned below is always formed of a positive photoresist.

Before the photolithographic process is performed, a mask 20 must be formed according to the design of the desired integrated circuits. The mask 20 comprises a transparent substrate 22 formed of glass or quartz and a plurality of opaque patterns 24 of chromium film is formed on a surface of the substrate 22. An exposure process is performed using the mask 20 on a semiconductor wafer 10, and then the semiconductor wafer 10 is placed in a developer to perform a development process. Completing the development process, several resin processes are performed to remove the developer and the dissolved photoresist to form photoresist patterns 26 on the semiconductor wafer 10, as shown in FIG. 3. An etching process is performed to remove a portion of an amorphous layer 16 that is not covered by the photoresist patterns 26 down to a surface of the dielectric layer 16 so as to form the shape of storage nodes 30, as shown in FIG. 4. The photoresist pattern 26 serves as a hard mask during etching process.

However, optical proximity effects cause the formation of a rounded corner on each isolated photoresist pattern 26, which are different from the rectangular corner of the design pattern. The reason for this is that optical proximity effects cause different regions of the photoresist layer 18 to receive different exposure levels, though the applied exposure is the same. The corners of the photoresist pattern 26 are overexposed and form rounded corners. Serious optical proximity effects will cause the occurrence of end-of-line shortening, meaning that the size of the photoresist pattern 26 is smaller than that of the design pattern (illustrated with dotted lines in FIG. 3). This end-of-line shortening causes the size of the subsequently formed storage nodes 30 to be smaller than that of the design and thereby reduces the capacity of the storage nodes 30.

Please refer to FIG. 5 to FIG. 9 of diagrams of a photolithographic process according another prior art. The photolithographic process is used to define storage nodes of a DRAM on a semiconductor wafer 40. The semiconductor wafer 40 comprises a substrate 42, a dielectric layer 43 formed of silicon oxide, a plurality of node contacts 44 formed of doped polysilicon in the dielectric layer 43, an amorphous silicon layer 45 positioned on a surface of the dielectric layer 43 and covering each node contact 44, and a photoresist layer covering a surface of the semiconductor wafer 40. The amorphous silicon layer 45 is used to form storage nodes of the DRAM.

The photolithographic process uses two masks 51 and 55, which replace the single mask used by the previously mentioned prior art photolithographic process. The mask 51 comprises a transparent substrate 52 and a plurality of opaque bands 53 positioned on a surface of the substrate 52, as shown in FIG. 6. The mask 55 comprises a transparent substrate 56 and a plurality of opaque bands 57 positioned on a surface of the substrate 56, as shown in FIG. 7. A double exposure process is performed using the mask 51 and 55, meaning that first an exposure process using the mask 51 is performed, followed by a second exposure process using the mask 55 performed on the semiconductor wafer 40.

Completing the exposure process, a development and several resin processes are performed to remove the developer and dissolved photoresist from the semiconductor wafer 40. A plurality of photoresist patterns 49 are thus formed at positions that correspond to the overlapping areas of the bands 53 and 57, as shown in FIG. 8. An etching process is then performed to remove a portion of the amorphous layer 45 that is not covered by the photoresist patterns 49 down to the surface of the dielectric layer 43 so as to form the storage nodes 50, as shown in FIG. 9. The photoresist patterns 49 serve as hard masks during the etching process.

Although the double exposure process reduces the influence of the end-of-line shortening caused by optical proximity effects, portions of the photoresist layer 47 are exposed twice, forming a plurality of overexposure areas 48 on the semiconductor wafer 40. This overexposure causes more severe optical proximity effects, which in turn round corners of the adjacent photoresist patterns 49. Because the size of the photoresist patterns 49 are smaller than that of the design, the size of the subsequently formed storage nodes 50 are also smaller than the design size. Consequently, the capacity of the storage nodes 50 is reduced.

### SUMMARY OF THE INVENTION

It is therefore a primary objective of the present invention to provide a method of forming storage nodes in a dynamic random access memory (DRAM) on a semiconductor wafer to solve the above problem.

In a preferred embodiment, the present invention provides a method of forming storage nodes in a dynamic random access memory (DRAM) on a semiconductor wafer to define the position and the size of the storage nodes by performed two exposure processes. The semiconductor wafer comprises a substrate, a thin film layer positioned on the substrate, and a photoresist layer positioned on the thin film layer. The method comprises two exposure processes. The first exposure process is performed to form first exposure regions that are linear and parallel with each other on the photoresist layer. The second exposure process is performed to form second exposure regions that are interlaced with and perpendicular to each other on the photoresist layer. Performing a development process on the first exposure regions and the second exposure regions of the photoresist layer removes the first exposure regions and the second exposure regions of the photoresist layer to form an array photoresist layer on the thin film layer. The array photoresist layer is used as a mask to perform an etching process to remove portions of the thin film layer not covered by the array photoresist layer so as to form an array thin film layer, the array thin film layer being used as the storage nodes in the DRAM.

It is an advantage of the present invention that a first exposure process is performed to form linear and parallel exposure regions followed by performing a second exposure process to form interlaced and perpendicular exposure regions for defining the position of the storage nodes so as to decrease optical proximity effects. The storage nodes in the DRAM formed by the present invention are slightly larger than the design pattern. The larger storage nodes increase the capacity of the storage node and are compensation for the size reduction of the storage node in subsequent etching and cleaning processes. Consequently, the size of the formed storage node is approximately the same as that of the design pattern, resolving the end-of-line shorting problem.

These and other objectives of the present invention will no doubt become obvious to those of ordinary skill in the art after reading the following detailed description of the preferred embodiment which is illustrated in the various figures and drawings.

### BRIEF DESCRIPTION OF THE DRAWINGS

FIG. 1 is a cross-sectional diagram of a semiconductor wafer according to the prior art.

FIG. 2 is an overhead diagram of a mask pattern according to the prior art.

FIG. 3 is an overhead diagram of a photoresist pattern formed according to the prior art.

FIG. 4 is a cross-sectional diagram of a storage node formed according to the prior art.

FIG. 5 is a cross-sectional diagram of a semiconductor wafer according to the prior art.

FIG. 6 is an overhead diagram of a first mask pattern according to the prior art.

FIG. 7 is an overhead diagram of a second mask pattern according to the prior art.

FIG. 8 is an overhead diagram of a photoresist pattern formed according to the prior art.

FIG. 9 is a cross-sectional diagram of a storage node formed according to the prior art.

FIG. 10 is a cross-sectional diagram of a semiconductor wafer according to the present invention.

FIG. 11 is an overhead diagram of a first mask pattern according to the present invention.

FIG. 12 is an overhead diagram of a second mask pattern according to the present invention.

FIG. 13 is an overhead diagram of a photoresist pattern formed according to the present invention.

FIG. 14 is a cross-sectional diagram of a storage node formed according to the present invention.

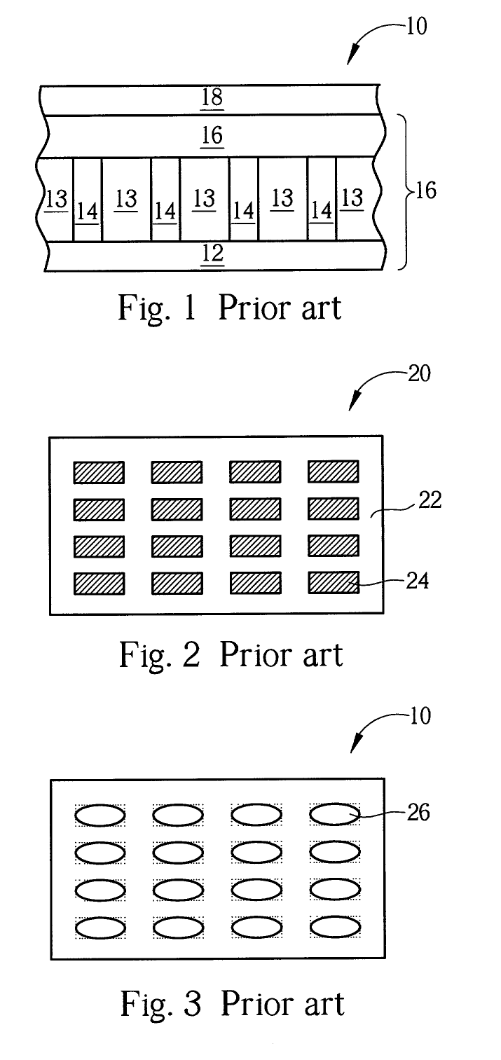

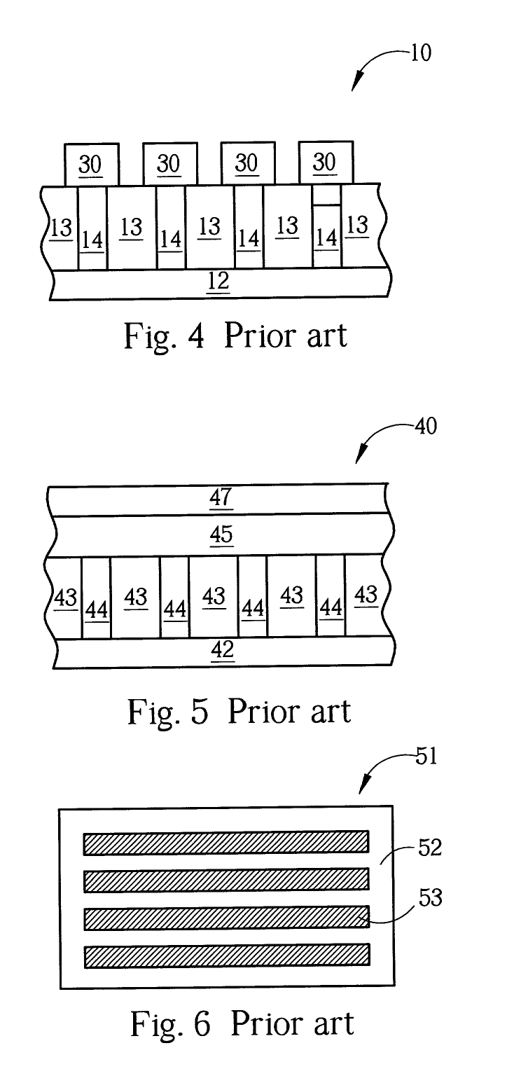

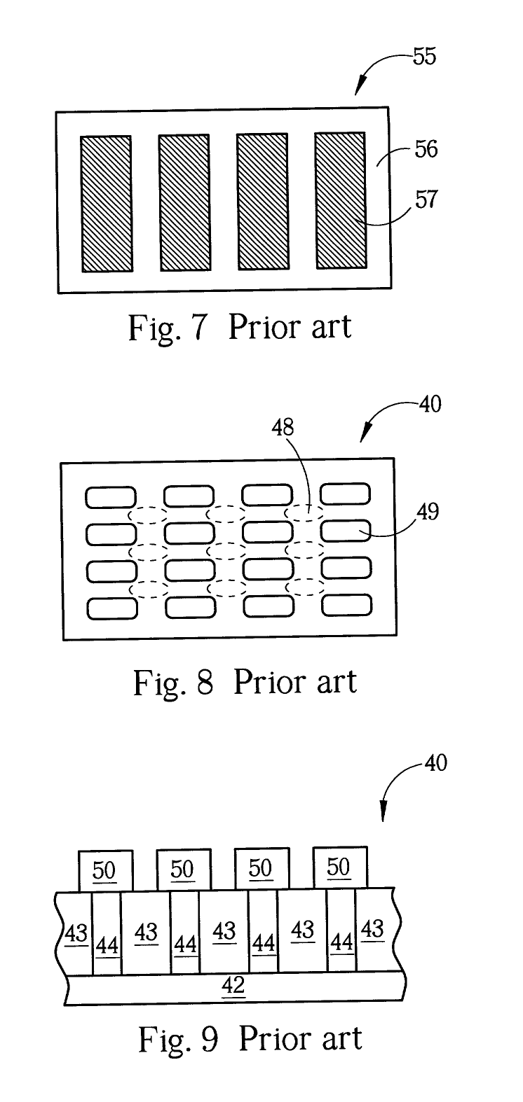

### DETAILED DESCRIPTION OF THE PREFERRED EMBODEMENT

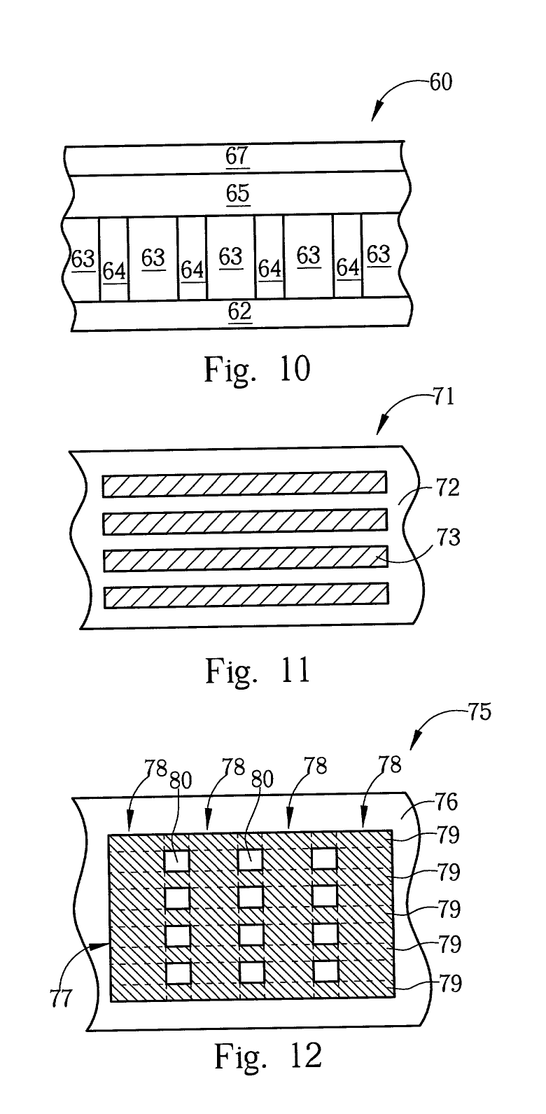

Please refer to FIG. 10 to FIG. 14 of diagrams of a photolithographic process according to the present invention. The photolithographic process is used to define storage nodes of a DRAM on a semiconductor wafer 60. As shown in FIG. 10, the semiconductor wafer 60 comprises a silicon substrate 62, a dielectric layer 63 formed of silicon oxide on the surface of silicon substrate 62, a plurality of node contacts 64 formed of doped polysilicon in the dielectric layer 63, an amorphous silicon layer 65 positioned on the surface of the dielectric layer 63 and covering the each node contact 64, and a photoresist layer 67 positioned on the surface the semiconductor wafer 60. The amorphous silicon layer 65 is used to form storage nodes, and each of the node contacts is used to electrically connect to a drain of a MOS transistor and subsequently formed storage nodes 70.

Before the photolithographic process is performed, a mask 71 and a mask 75 must be made according to the design of the desired integrated circuit, as shown in FIG. 11 and FIG. 12. A double exposure process is performed using the mask 71 and the mask 75, meaning that a first exposure process is performed using the mask 71 to transfer a first pattern 73 onto the photoresist layer 67, and a second exposure process is performed using the mask 75 to transfer the second pattern 77 onto the photoresist layer 67. The semiconductor wafer 60 is then placed into a developer to undergo a development process.

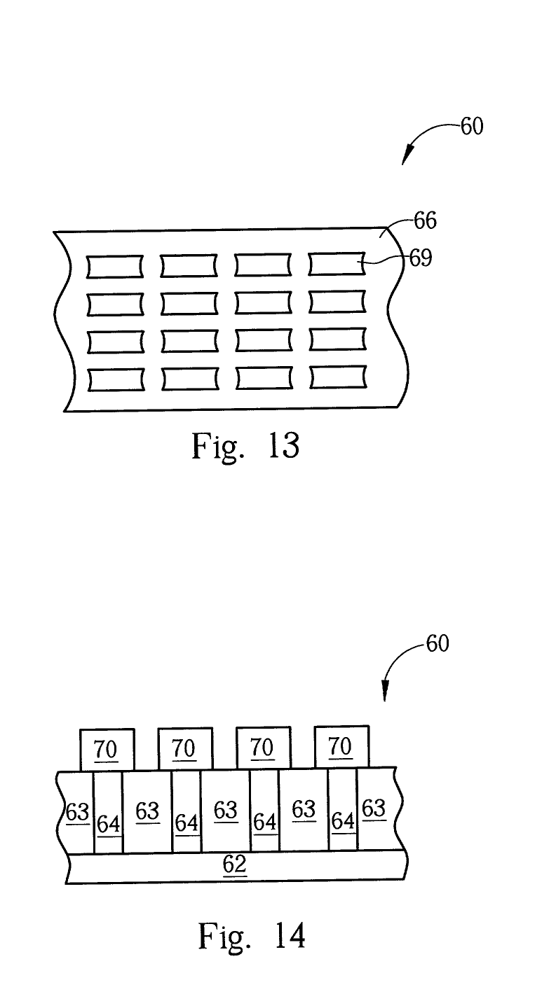

After the development process is completed, several resin processes are then performed to remove dissolved photoresist and the developer. After the exposure, development, and resin processes, a plurality of photoresist patterns 69 are formed on the semiconductor wafer 60, as shown in FIG. 13. An etching process is then performed to remove a portion of the amorphous silicon layer 65 not covered by the photoresist patterns 69 down to the surface of the dielectric layer 63 so as to form storage nodes 70, as shown in FIG. 14. The photoresist patterns 69 serve as a hard mask during the etching process.

The mask 71 comprises a transparent 72 formed of glass or quartz, and a mask pattern 73 formed of chromium film on the surface of the transparent substrate 72. The mask pattern 73 comprises a plurality of non-intersecting opaque bands 74. The bands 74 are parallel to each other, and each of the bands 74 covers an area that corresponds to the positions of a plurality of photoresist patterns 69 on the semiconductor wafer 60. The mask 75 comprises a transparent substrate 76 formed of glass or quartz, and a pattern 77 formed of chromium film on the surface of the transparent substrate 76. The mask pattern 77 comprises a plurality of rectangles interlaced with and perpendicular to each other formed on the chromium film and each rectangle corners positioned on the storage nodes. It means that the opaque areas of mask pattern 77 cover the areas that correspond to the positions of a plurality of photoresist patterns 69. The present invention uses the mask 71 to form a plurality of lines parallel to each other and covering each storage node followed by a exposure process using mask pattern 75 to cut the lines covering storage nodes to form a plurality of the array photoresist patterns 69.

During the exposure process, a light beam penetrates through the transparent areas 80 on the mask 75 to the photoresist layer 67. Optical proximity effects cause an underexposure on areas of the photoresist pattern 69 that correspond to the corners of a transparent area 80. The formed photoresist patterns 69 possess slightly enlarged corners due to underexposure, and so the size of the formed photoresist patterns 69 is also slightly larger than that of the design patterns. These slightly larger photoresist patterns 69 not only compensate for losses in the amorphous layer during the etching process, but they also compensate for the reduction in size of the storage node in the subsequent resin process. Consequently, the size of the resulting formed storage node is approximately the same as the design pattern.

Compared to the prior art, the present invention performs a double exposure process using a first mask with a cross-hatched mask pattern and a second mask with a banded mask pattern to reduce the effects of end-of-line shorting. The present invention controls optical proximity effects to cause an underexposure at the corners of the photoresist patterns 69 and to form a slightly larger storage node to compensate for losses in the subsequent etching and resin processes. Consequently, the formed storage node is approximately the same size as the design pattern, resolving the end-of-line shortening problem.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming storage nodes in a dynamic random access memory (DRAM) on a semiconductor wafer, the semiconductor wafer comprising a substrate, a thin film layer positioned on the substrate, and a photoresist layer positioned on the thin film layer, the method comprising:
performing a first exposure process to form first exposure regions that are linear and parallel with each other on the photoresist layer;
performing a second exposure process to form second exposure regions that are interlaced with and perpendicular to each other on the photoresist layer;
performing a development process on the first exposure regions and the second exposure regions of the photoresist layer;
removing the first exposure regions and the second exposure regions of the photoresist layer to form an array photoresist layer on the thin film layer; and
using the array photoresist layer as a mask to perform an etching process to remove portions of the thin film layer not covered by the array photoresist layer so as to form an array thin film layer, the array thin film layer being used as the storage nodes in the DRAM.

2. The method of claim 1 wherein the method is used to prevent rounding corner effects, end-of-line shortening, or other optical proximity effects to patterns of the photoresist layer.

3. A method for preventing optical proximity effects in a photolithography process, the photolithography process being used to define an array pattern of a photoresist layer on a semiconductor wafer, the semiconductor wafer comprising a substrate, the photoresist layer positioned on the substrate, the method comprising:
performing a first exposure process to form a first pattern used to define first exposure regions that are linear and parallel with each other on the photoresist layer;
performing a second exposure process to form a second pattern used to define second exposure patterns that are interlaced with and perpendicular to each other on the photoresist layer; and
performing a development process to the photoresist layer so as to define the array pattern of the photoresist layer.

4. The method of claim 3 wherein the semiconductor wafer is used for forming a dynamic random access memory (DRAM), and the array pattern of the photoresist layer is used to define positions of storage nodes in the DRAM.

5. The method of claim 3 wherein the optical proximity effects comprise rounding corner effects, or end-of-line shortening of patterns.

6. A method of forming storage nodes in a dynamic random access memory (DRAM) on a semiconductor wafer, the semiconductor wafer comprising a substrate, a thin film layer positioned on the substrate, and a photoresist layer positioned on the thin film layer, the method comprising:
performing a first exposure process to form a plurality of unexposed regions that are linear and parallel with each other on the photoresist layer;
performing a second exposure process to form a plurality of discrete exposed regions in the unexposed regions;
performing a development process on the photoresist layer so as to form an array photoresist layer; and
using the array photoresist layer as a mask to perform an etching process to remove portions of the thin film layer not covered by the array photoresist layer so as to form an array thin film layer, the array thin film layer being used as the storage nodes in the DRAM.
